(19) United States
(12) Patent Application Publication
(10) Pub. No.: US 2018/0052560 A1
(43) Pub. Date: Feb. 22, 2018

(54) INPUT DEVICE AND CONTROLLING METHOD THEREOF

(71) Applicant: LG ELECTRONICS INC., Seoul (KR)

(72) Inventors: Hyungjoo KANG, Seoul (KR); Salkmann JI, Seoul (KR); Samnyol HONG, Seoul (KR)

(73) Assignee: LG ELECTRONICS INC., Seoul (KR)

(21) Appl. No.: 15/600,434

(22) Filed: May 19, 2017

(30) Foreign Application Priority Data
Aug. 17, 2016 (KR) 10-2016-0104121

(51) Int. Cl. G06F 3/041; G06F 3/0354; G06F 3/046; G06F 3/02; H03K 5/153

(52) U.S. Cl. CPC G06F 3/0416; G06F 3/03547; G06F 3/046; G08B 6/00; H03K 5/153; H03K 2217/96038; G06F 3/0202

(57) ABSTRACT

Disclosed is an input device. The input device includes a first coil configured to receive a touch input from a user and transmit the received touch input to another coil, a second coil configured, when the first coil is moved in a first direction according to the received touch input, to be electrically connected to the first coil according to a movement of the first coil and generate induced electromotive force, a third coil, a fourth coil, and a sensing unit configured to sense a size of the induced electromotive force generated according to the movement of at least one selected from the group consisting of coils and a pressure size of the touch input.

Pursuant to 35 U.S.C. §119(a), this application claims the benefit of earlier filing date and right of priority to Korean Application No. 10-2016-0104121, filed on Aug. 17, 2016, the contents of which are all hereby incorporated by reference herein in its entirety.

### BACKGROUND OF THE INVENTION

### Field of the Invention

The present invention relates to an input device and controlling method thereof, and more particularly, to an input device capable of subdividing and processing a touch input value using electromagnetic induction and controlling method thereof.

### Discussion of the Related Art

According to the development of IT industry, it is very important to input a command in a computer or a mobile device. A command input is applied using a keyboard, a mouse, a touch input on a touch screen, or the like.

According to the conventional art, when a physical keyboard is used, if a touch input to a specific key is received from a user, only one function corresponding to the specific key can be executed but other functions cannot be executed. For example, when a cursor is moved on a computer screen, a user can move the cursor with a specific key only but has difficulty in selecting an icon with the cursor. Therefore, in order to execute another function corresponding to the icon, the user should separately push a key other than the specific key, thereby causing a problem of making the user feel inconvenient.

### SUMMARY OF THE INVENTION

Accordingly, embodiments of the present invention are directed to a mobile terminal and controlling method thereof that substantially obviate one or more problems due to limitations and disadvantages of the related art.

One object of the present invention is to provide an input device and controlling method thereof, by which various functions can be performed with a touch input to a single input key using induced electromotive force.

Another object of the present invention is to provide an input device and controlling method thereof, by which an output of a sensing unit can be differently regulated depending on the pressure size of a touch input in a specific direction received from a specific coil.

Another object of the present invention is to provide an input device and controlling method thereof, by which a plurality of coils can be controlled independently at a time in a time-divided prescribed time in a manner of time-diving the prescribed time.

Further object of the present invention is to provide an input device and controlling method thereof, by which a size of a specific image can be adjusted if a specific coil is moved in a specific direction in the state that a gallery application including the specific image is running.

Technical tasks obtainable from the present invention are non-limited by the above-mentioned technical tasks. And, other unmentioned technical tasks can be clearly understood from the following description by those having ordinary skill in the technical field to which the present invention pertains.

Additional advantages, objects, and features of the invention will be set forth in the disclosure herein as well as the accompanying drawings. Such aspects may also be appreciated by those skilled in the art based on the disclosure herein.

To achieve these objects and other advantages and in accordance with the purpose of the invention, as embodied and broadly described herein, an input device may include a first coil configured to receive a touch input from a user and transmit the received touch input to at least one another coil, a second coil configured, when the first coil is moved in a first direction according to the received touch input, to be electrically connected to the first coil according to a movement of the first coil and generate induced electromotive force, a third coil configured, when the first coil is moved in a second direction according to the received touch input, to be electrically connected to the first coil according to the movement of the first coil and generate induced electromotive force, a fourth coil configured, when the first coil is moved in a third direction according to the received touch input, to be electrically connected to the first coil according to the movement of the first coil and generate induced electromotive force, and a sensing unit configured to sense a size of the induced electromotive force generated according to the movement of at least one of the first coil, the second coil, the third coil and the fourth coil and a pressure size of the touch input.

In another aspect of the present invention, as embodied and broadly described herein, a method of controlling an input device may include receiving a touch input from a user, transmitting the received touch input to at least one another coil through the first coil, electrically connecting the first coil to a second coil according to a movement of the first coil when the first coil is moved in a first direction according to the received touch input, generating an induced electromotive force based on the connected first and second coils, electrically connecting the first coil to a third coil according to the movement of the first coil when the first coil is moved in a second direction according to the received touch input, generating the induced electromotive force based on the connected first and third coils, electrically connecting the first coil to a fourth coil according to the movement of the first coil when the first coil is moved in a third direction according to the received touch input, generating the induced electromotive force based on the connected first and fourth coils, and sensing a size of the induced electromotive force generated according to the movement of at least one of the first coil, the second coil, the third coil and the fourth coil and a pressure size of the touch input.

Effects obtainable from the present invention may be non-limited by the above mentioned effect. And, other unmentioned effects can be clearly understood from the following description by those having ordinary skill in the technical field to which the present invention pertains.

It is understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. The above and other aspects, features, and advantages of the present invention will become more apparent upon consideration of the following description of preferred embodiments, taken in conjunction with the accompanying drawing figures. In the drawings:

FIG. 1A is a block diagram for setting a mobile terminal according to an embodiment of the present invention;

FIGS. 1B and 1C are conceptual diagrams from different perspectives of an example of a mobile terminal related to the present invention;

FIG. 2 is a diagram to describe a configuration of an input device according to an embodiment of the present invention;

FIG. 3 is a flowchart of a controlling method of an input device according to an embodiment of the present invention;

FIG. 4 is a perspective view diagram of an input device according to an embodiment of the present invention;

FIG. 5 is a lateral view diagram of an input device according to an embodiment of the present invention;

FIG. 6 is a diagram to describe a first coil displacement and a sensor output when a first coil is moved in the state that a second coil is fixed according to an embodiment of the present invention;

FIG. 7 is a diagram to describe time-division of a prescribed time and control of at least one of the second coil, the third coil and the fourth coil independent from a corresponding time in the time-divided prescribed time;

FIG. 8 is a diagram to describe a first coil displacement and a sensor output when a first coil is moved in the state that a fourth coil is fixed;

FIG. 9 is a diagram to describe an input device embodied as a product according to an embodiment of the present invention;

FIG. 10 is a diagram to describe an input device embodied as a PCB product according to an embodiment of the present invention;

FIG. 11 is a diagram to describe an input device embodied as an instrument according to an embodiment of the present invention;

FIG. 12 is a diagram to describe adjusting the size of a specific image and moving a specific image using an input device according to an embodiment of the present invention;

FIG. 13 is a diagram to describe execution of a function corresponding to a specific icon indicated by a specific pointer using an input device according to an embodiment of the present invention;

FIG. 14 is a diagram to describe adjustment of a moving picture play speed using an input device in a state that a moving picture application is running according to an embodiment of the present invention;

FIG. 15 is a diagram to describe editing of a document using an input device according to an embodiment of the present invention;

FIG. 16 is a diagram to describe grouping of a plurality of icons using an input device according to an embodiment of the present invention; and

FIG. 17 is a diagram to describe application of an input device to a keyboard according to an embodiment of the present invention.

### DETAILED DESCRIPTION OF THE INVENTION

Description will now be given in detail according to exemplary embodiments disclosed herein, with reference to the accompanying drawings. For the sake of brief description with reference to the drawings, the same or equivalent components may be provided with the same reference numbers, and description thereof will not be repeated. In general, a suffix such as “module” and “unit” may be used to refer to elements or components. Use of such a suffix herein is merely intended to facilitate description of the specification, and the suffix itself is not intended to give any special meaning or function. In the present disclosure, that which is well-known to one of ordinary skill in the relevant art has generally been omitted for the sake of brevity. The accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are generally only used to distinguish one element from another.

It will be understood that when an element is referred to as being “connected with” another element, the element can be connected with the other element or intervening elements may also be present. In contrast, when an element is referred to as being “directly connected with” another element, there are no intervening elements present.

A singular representation may include a plural representation unless it represents a definitely different meaning from the context.

Terms such as “include” or “has” are used herein and should be understood that they are intended to indicate an existence of several components, functions or steps, disclosed in the specification, and it is also understood that greater or fewer components, functions, or steps may likewise be utilized.

Mobile terminals presented herein may be implemented using a variety of different types of terminals. Examples of such terminals include cellular phones, smart phones, user equipment, laptop computers, digital broadcast terminals, personal digital assistants (PDAs), portable multimedia players (PMPs), navigators, portable computers (PCs), slate PCs, tablet PCs, ultra books, wearable devices (for example, smart watches, smart glasses, head mounted displays (HMDs)), and the like.

By way of non-limiting example only, further description will be made with reference to particular types of mobile terminals. However, such teachings apply equally to other types of terminals, such as those types noted above. In addition, these teachings may also be applied to stationary terminals such as digital TV, desktop computers, and the like.

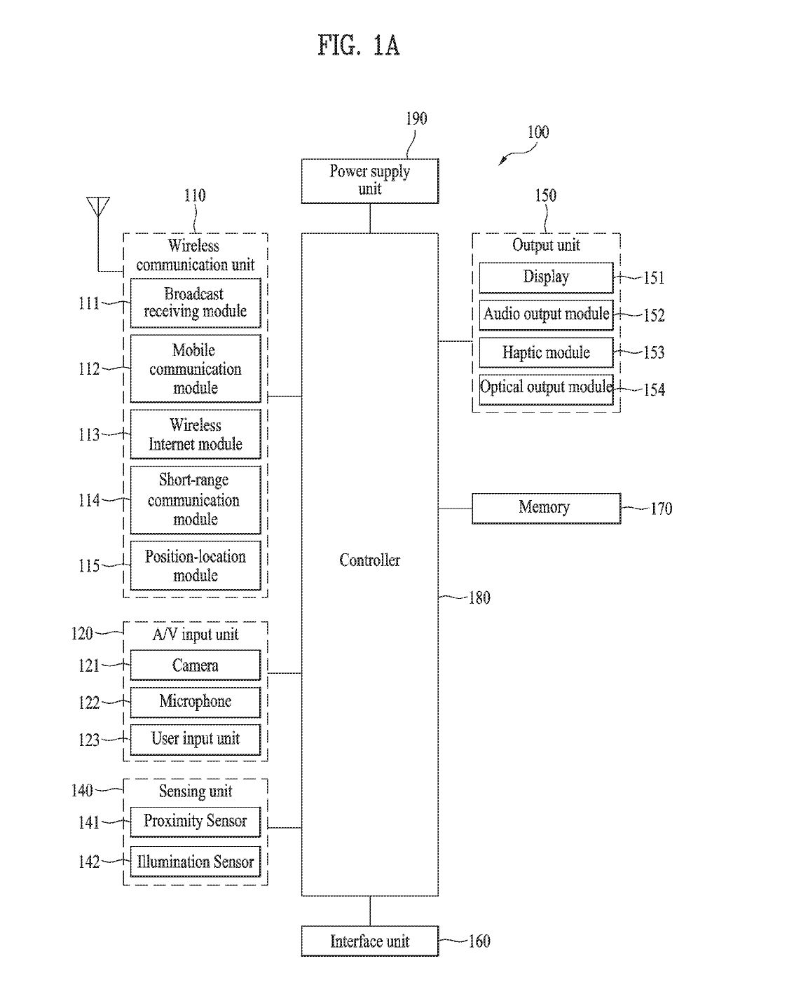

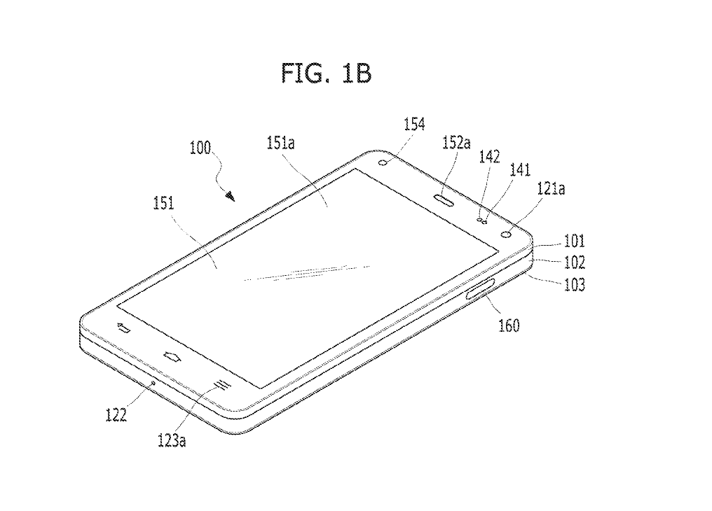

Reference is now made to FIGS. 1A-1C, where FIG. 1A is a block diagram of a mobile terminal in accordance with the present disclosure, and FIGS. 1B and 1C are conceptual views of one example of the mobile terminal, viewed from different directions.

The mobile terminal 100 is shown having components such as a wireless communication unit 110, an input unit 120, a sensing unit 140, an output unit 150, an interface unit 160, a memory 170, a controller 180, and a power supply unit 190. It is understood that implementing all of the illustrated components is not a requirement, and that greater or fewer components may alternatively be implemented. Referring now to FIG. 1A, the mobile terminal 100 is shown having wireless communication unit 110 configured with several commonly implemented components.

The wireless communication unit 110 typically includes one or more modules which permit communications such as wireless communications between the mobile terminal 100 and a wireless communication system, communications between the mobile terminal 100 and another mobile terminal, communications between the mobile terminal 100 and an external server. Further, the wireless communication unit 110 typically includes one or more modules which connect the mobile terminal 100 to one or more networks.

To facilitate such communications, the wireless communication unit 110 includes one or more of a broadcast receiving module 111, a mobile communication module 112, a wireless Internet module 113, a short-range communication module 114, and a location information module 115.

The input unit 120 includes a camera 121 for obtaining images or video, a microphone 122, which is one type of audio input device for inputting an audio signal, and a user input unit 123 (for example, a touch key, a push key, a mechanical key, a soft key, and the like) for allowing a user to input information. Data (for example, audio, video, image, and the like) is obtained by the input unit 120 and may be analyzed and processed by controller 180 according to device parameters, user commands, and combinations thereof.

The sensing unit 140 is typically implemented using one or more sensors configured to sense internal information of the mobile terminal, the surrounding environment of the mobile terminal, user information, and the like. For example, in FIG. 1A, the sensing unit 140 is shown having a proximity sensor 141 and an illumination sensor 142. If desired, the sensing unit 140 may alternatively or additionally include other types of sensors or devices, such as a touch sensor, an acceleration sensor, a magnetic sensor, a G-sensor, a gyroscope sensor, a motion sensor, an RGB sensor, an infrared (IR) sensor, a finger scan sensor, a ultrasonic sensor, an optical sensor (for example, camera 121), a microphone 122, a battery gauge, an environment sensor (for example, a barometer, a hygrometer, a thermometer, a radiation detection sensor, a thermal sensor, and a gas sensor, among others), and a chemical sensor (for example, an electronic nose, a health care sensor, a biometric sensor, and the like), to name a few. The mobile terminal 100 may be configured to utilize information obtained from sensing unit 140, and in particular, information obtained from one or more sensors of the sensing unit 140, and combinations thereof.

The output unit 150 is typically configured to output various types of information, such as audio, video, tactile output, and the like. The output unit 150 is shown having a display unit 151, an audio output module 152, a haptic module 153, and an optical output module 154. The display unit 151 may have an inter-layered structure or an integrated structure with a touch sensor in order to facilitate a touch screen. The touch screen may provide an output interface between the mobile terminal 100 and a user, as well as function as the user input unit 123 which provides an input interface between the mobile terminal 100 and the user.

The interface unit 160 serves as an interface with various types of external devices that can be coupled to the mobile terminal 100. The interface unit 160, for example, may include any of wired or wireless ports, external power supply ports, wired or wireless data ports, memory card ports, ports for connecting a device having an identification module, audio input/output (I/O) ports, video I/O ports, earphone ports, and the like. In some cases, the mobile terminal 100 may perform assorted control functions associated with a connected external device, in response to the external device being connected to the interface unit 160.

The memory 170 is typically implemented to store data to support various functions or features of the mobile terminal 100. For instance, the memory 170 may be configured to store application programs executed in the mobile terminal 100, data or instructions for operations of the mobile terminal 100, and the like. Some of these application programs may be downloaded from an external server via wireless communication. Other application programs may be installed within the mobile terminal 100 at time of manufacturing or shipping, which is typically the case for basic functions of the mobile terminal 100 (for example, receiving a call, placing a call, receiving a message, sending a message, and the like). It is common for application programs to be stored in the memory 170, installed in the mobile terminal 100, and executed by the controller 180 to perform an operation (or function) for the mobile terminal 100.

The controller 180 typically functions to control overall operation of the mobile terminal 100, in addition to the operations associated with the application programs. The controller 180 processes signals, data, informations and the like inputted or outputted through the above-mentioned components and/or runs application programs saved in the memory 170, thereby processing or providing a user with appropriate informations and/or functions.

The controller 180 may provide or process information or functions appropriate for a user by processing signals, data, information and the like, which are input or output by the various components depicted in FIG. 1A, or activating application programs stored in the memory 170. As one example, the controller 180 controls some or all of the components illustrated in FIG. 1A according to the execution of an application program that have been stored in the memory 170.

The power supply unit 190 can be configured to receive external power or provide internal power in order to supply appropriate power required for operating elements and components included in the mobile terminal 100. The power supply unit 190 may include a battery, and the battery may be configured to be embedded in the terminal body, or configured to be detachable from the terminal body.

At least one portion of the respective components mentioned in the foregoing description can cooperatively operate to embody operations, controls or controlling methods of the mobile terminal according to various embodiments of the present invention mentioned in the following description. Moreover, the operations, controls or controlling methods of the mobile terminal can be embodied in the mobile terminal by running at least one or more application programs saved in the memory 170.

Referring still to FIG. 1A, various components depicted in this figure will now be described in more detail.

Regarding the wireless communication unit 110, the broadcast receiving module 111 is typically configured to receive a broadcast signal and/or broadcast associated information from an external broadcast managing entity via a broadcast channel. The broadcast channel may include a satellite channel, a terrestrial channel, or both. In some embodiments, two or more broadcast receiving modules 111 may be utilized to facilitate simultaneously receiving of two or more broadcast channels, or to support switching among broadcast channels.

The mobile communication module 112 can transmit and/or receive wireless signals to and from one or more network entities. Typical examples of a network entity include a base station, an external mobile terminal, a server, and the like. Such network entities form part of a mobile communication network, which is constructed according to technical standards or communication methods for mobile communications (for example, Global System for Mobile Communication (GSM), Code Division Multi Access (CDMA), CDMA2000 (Code Division Multi Access 2000), EV-DO (Enhanced Voice-Data Optimized or Enhanced Voice-Data Only), Wideband CDMA (WCDMA), High Speed Downlink Packet access (HSDPA), HSUPA (High Speed Uplink Packet Access), Long Term Evolution (LTE), LTE-A (Long Term Evolution-Advanced), and the like).

Examples of wireless signals transmitted and/or received via the mobile communication module 112 include audio call signals, video (telephony) call signals, or various formats of data to support communication of text and multimedia messages.

The wireless Internet module 113 is configured to facilitate wireless Internet access. This module may be internally or externally coupled to the mobile terminal 100. The wireless Internet module 113 may transmit and/or receive wireless signals via communication networks according to wireless Internet technologies.

Examples of such wireless Internet access include Wireless LAN (WLAN), Wireless Fidelity (Wi-Fi), Wi-Fi Direct, Digital Living Network Alliance (DLNA), Wireless Broadband (WiBro), Worldwide Interoperability for Microwave Access (WiMAX), High Speed Downlink Packet Access (HSDPA), HSUPA (High Speed Uplink Packet Access), Long Term Evolution (LTE), LTE-A (Long Term Evolution-Advanced), and the like. The wireless Internet module 113 may transmit/receive data according to one or more of such wireless Internet technologies, and other Internet technologies as well.

In some embodiments, when the wireless Internet access is implemented according to, for example, WiBro, HSDPA, HSUPA, GSM, CDMA, WCDMA, LTE, LTE-A and the like, as part of a mobile communication network, the wireless Internet module 113 performs such wireless Internet access. As such, the Internet module 113 may cooperate with, or function as, the mobile communication module 112.

The short-range communication module 114 is configured to facilitate short-range communications. Suitable technologies for implementing such short-range communications include BLUETOOTH™, Radio Frequency IDentification (RFID), Infrared Data Association (IrDA), Ultra-WideBand (UWB), ZigBee, Near Field Communication (NFC), Wireless-Fidelity (Wi-Fi), Wi-Fi Direct, Wireless USB (Wireless Universal Serial Bus), and the like. The short-range communication module 114 in general supports wireless communications between the mobile terminal 100 and a wireless communication system, communications between the mobile terminal 100 and another mobile terminal 100, or communications between the mobile terminal and a network where another mobile terminal 100 (or an external server) is located, via wireless area networks. One example of the wireless area networks is a wireless personal area networks.

In some embodiments, another mobile terminal (which may be configured similarly to mobile terminal 100) may be a wearable device, for example, a smart watch, a smart glass or a head mounted display (HMD), which is able to exchange data with the mobile terminal 100 (or otherwise cooperate with the mobile terminal 100). The short-range communication module 114 may sense or recognize the wearable device, and permit communication between the wearable device and the mobile terminal 100. In addition, when the sensed wearable device is a device which is authenticated to communicate with the mobile terminal 100, the controller 180, for example, may cause transmission of data processed in the mobile terminal 100 to the wearable device via the short-range communication module 114. Hence, a user of the wearable device may use the data processed in the mobile terminal 100 on the wearable device. For example, when a call is received in the mobile terminal 100, the user may answer the call using the wearable device. Also, when a message is received in the mobile terminal 100, the user can check the received message using the wearable device.

The location information module 115 is generally configured to detect, calculate, derive or otherwise identify a position of the mobile terminal. As an example, the location information module 115 includes a Global Position System (GPS) module, a Wi-Fi module, or both. If desired, the location information module 115 may alternatively or additionally function with any of the other modules of the wireless communication unit 110 to obtain data related to the position of the mobile terminal. As one example, when the mobile terminal uses a GPS module, a position of the mobile terminal may be acquired using a signal sent from a GPS satellite. As another example, when the mobile terminal uses the Wi-Fi module, a position of the mobile terminal can be acquired based on information related to a wireless access point (AP) which transmits or receives a wireless signal to or from the Wi-Fi module.

The input unit 120 may be configured to permit various types of input to the mobile terminal 120. Examples of such input include audio, image, video, data, and user input. Image and video input is often obtained using one or more cameras 121. Such cameras 121 may process image frames of still pictures or video obtained by image sensors in a video or image capture mode. The processed image frames can be displayed on the display unit 151 or stored in memory 170. In some cases, the cameras 121 may be arranged in a matrix configuration to permit a plurality of images having various angles or focal points to be input to the mobile terminal 100. As another example, the cameras 121 may be located in a stereoscopic arrangement to acquire left and right images for implementing a stereoscopic image.

The microphone 122 is generally implemented to permit audio input to the mobile terminal 100. The audio input can be processed in various manners according to a function being executed in the mobile terminal 100. If desired, the microphone 122 may include assorted noise removing algorithms to remove unwanted noise generated in the course of receiving the external audio.

The user input unit 123 is a component that permits input by a user. Such user input may enable the controller 180 to control operation of the mobile terminal 100. The user input unit 123 may include one or more of a mechanical input element (for example, a key, a button located on a front and/or rear surface or a side surface of the mobile terminal 100, a dome switch, a jog wheel, a jog switch, and the like), or a touch-sensitive input, among others. As one example, the touch-sensitive input may be a virtual key or a soft key, which is displayed on a touch screen through software processing, or a touch key which is located on the mobile terminal at a location that is other than the touch screen. On the other hand, the virtual key or the visual key may be displayed on the touch screen in various shapes, for example, graphic, text, icon, video, or a combination thereof.

The sensing unit 140 is generally configured to sense one or more of internal information of the mobile terminal, surrounding environment information of the mobile terminal, user information, or the like. The controller 180 generally cooperates with the sending unit 140 to control operation of the mobile terminal 100 or execute data processing, a function or an operation associated with an application program installed in the mobile terminal based on the sensing provided by the sensing unit 140. The sensing unit 140 may be implemented using any of a variety of sensors, some of which will now be described in more detail.

The proximity sensor 141 may include a sensor to sense presence or absence of an object approaching a surface, or an object located near a surface, by using an electromagnetic field, infrared rays, or the like without a mechanical contact. The proximity sensor 141 may be arranged at an inner region of the mobile terminal covered by the touch screen, or near the touch screen.

The proximity sensor 141, for example, may include any of a transmissive type photoelectric sensor, a direct reflective type photoelectric sensor, a mirror reflective type photoelectric sensor, a high-frequency oscillation proximity sensor, a capacitance type proximity sensor, a magnetic type proximity sensor, an infrared rays proximity sensor, and the like. When the touch screen is implemented as a capacitance type, the proximity sensor 141 can sense proximity of a pointer relative to the touch screen by changes of an electromagnetic field, which is responsive to an approach of an object with conductivity. In this case, the touch screen (touch sensor) may also be categorized as a proximity sensor.

The term “proximity touch” will often be referred to herein to denote the scenario in which a pointer is positioned to be proximate to the touch screen without contacting the touch screen. The term “contact touch” will often be referred to herein to denote the scenario in which a pointer makes physical contact with the touch screen. For the position corresponding to the proximity touch of the pointer relative to the touch screen, such position will correspond to a position where the pointer is perpendicular to the touch screen. The proximity sensor 141 may sense proximity touch, and proximity touch patterns (for example, distance, direction, speed, time, position, moving status, and the like).

In general, controller 180 processes data corresponding to proximity touches and proximity touch patterns sensed by the proximity sensor 141, and cause output of visual information on the touch screen. In addition, the controller 180 can control the mobile terminal 100 to execute different operations or process different data according to whether a touch with respect to a point on the touch screen is either a proximity touch or a contact touch.

A touch sensor can sense a touch applied to the touch screen, such as display unit 151, using any of a variety of touch methods. Examples of such touch methods include a resistive type, a capacitive type, an infrared type, and a magnetic field type, among others. As one example, the touch sensor may be configured to convert changes of pressure applied to a specific part of the display unit 151, or convert capacitance occurring at a specific part of the display unit 151, into electric input signals. The touch sensor may also be configured to sense not only a touched position and a touched area, but also touch pressure and/or touch capacitance. A touch object is generally used to apply a touch input to the touch sensor. Examples of typical touch objects include a finger, a touch pen, a stylus pen, a pointer, or the like.

When a touch input is sensed by a touch sensor, corresponding signals may be transmitted to a touch controller. The touch controller may process the received signals, and then transmit corresponding data to the controller 180. Accordingly, the controller 180 may sense which region of the display unit 151 has been touched. Here, the touch controller may be a component separate from the controller 180, the controller 180, and combinations thereof.

In some embodiments, the controller 180 may execute the same or different controls according to a type of touch object that touches the touch screen or a touch key provided in addition to the touch screen. Whether to execute the same or different control according to the object which provides a touch input may be decided based on a current operating state of the mobile terminal 100 or a currently executed application program, for example.

The touch sensor and the proximity sensor may be implemented individually, or in combination, to sense various types of touches. Such touches includes a short (or tap) touch, a long touch, a multi-touch, a drag touch, a flick touch, a pinch-in touch, a pinch-out touch, a swipe touch, a hovering touch, and the like.

If desired, an ultrasonic sensor may be implemented to recognize position information relating to a touch object using ultrasonic waves. The controller 180, for example, may calculate a position of a wave generation source based on information sensed by an illumination sensor and a plurality of ultrasonic sensors. Since light is much faster than ultrasonic waves, the time for which the light reaches the optical sensor is much shorter than the time for which the ultrasonic wave reaches the ultrasonic sensor. The position of the wave generation source may be calculated using this fact. For instance, the position of the wave generation source may be calculated using the time difference from the time that the ultrasonic wave reaches the sensor based on the light as a reference signal.

The camera 121 typically includes at least one a camera sensor (CCD, CMOS etc.), a photo sensor (or image sensors), and a laser sensor.

Implementing the camera 121 with a laser sensor may allow detection of a touch of a physical object with respect to a 3D stereoscopic image. The photo sensor may be laminated on, or overlapped with, the display device. The photo sensor may be configured to scan movement of the physical object in proximity to the touch screen. In more detail, the photo sensor may include photo diodes and transistors at rows and columns to scan content received at the photo sensor using an electrical signal which changes according to the quantity of applied light. Namely, the photo sensor may calculate the coordinates of the physical object according to variation of light to thus obtain position information of the physical object.

The display unit 151 is generally configured to output information processed in the mobile terminal 100. For example, the display unit 151 may display execution screen information of an application program executing at the mobile terminal 100 or user interface (UI) and graphic user interface (GUI) information in response to the execution screen information.

In some embodiments, the display unit 151 may be implemented as a stereoscopic display unit for displaying stereoscopic images.

A typical stereoscopic display unit may employ a stereoscopic display scheme such as a stereoscopic scheme (a glass scheme), an auto-stereoscopic scheme (glassless scheme), a projection scheme (holographic scheme), or the like.

The audio output module 152 is generally configured to output audio data. Such audio data may be obtained from any of a number of different sources, such that the audio data may be received from the wireless communication unit 110 or may have been stored in the memory 170. The audio data may be output during modes such as a signal reception mode, a call mode, a record mode, a voice recognition mode, a broadcast reception mode, and the like. The audio output module 152 can provide audible output related to a particular function (e.g., a call signal reception sound, a message reception sound, etc.) performed by the mobile terminal 100. The audio output module 152 may also be implemented as a receiver, a speaker, a buzzer, or the like.

A haptic module 153 can be configured to generate various tactile effects that a user feels, perceive, or otherwise experience. A typical example of a tactile effect generated by the haptic module 153 is vibration. The strength, pattern and the like of the vibration generated by the haptic module 153 can be controlled by user selection or setting by the controller. For example, the haptic module 153 may output different vibrations in a combining manner or a sequential manner.

Besides vibration, the haptic module 153 can generate various other tactile effects, including an effect by stimulation such as a pin arrangement vertically moving to contact skin, a spray force or suction force of air through a jet orifice or a suction opening, a touch to the skin, a contact of an electrode, electrostatic force, an effect by reproducing the sense of cold and warmth using an element that can absorb or generate heat, and the like.

The haptic module 153 can also be implemented to allow the user to feel a tactile effect through a muscle sensation such as the user's fingers or arm, as well as transferring the tactile effect through direct contact. Two or more haptic modules 153 may be provided according to the particular configuration of the mobile terminal 100.

An optical output module 154 can output a signal for indicating an event generation using light of a light source. Examples of events generated in the mobile terminal 100 may include message reception, call signal reception, a missed call, an alarm, a schedule notice, an email reception, information reception through an application, and the like.

A signal output by the optical output module 154 may be implemented in such a manner that the mobile terminal emits monochromatic light or light with a plurality of colors. The signal output may be terminated as the mobile terminal senses that a user has checked the generated event, for example.

The interface unit 160 serves as an interface for external devices to be connected with the mobile terminal 100. For example, the interface unit 160 can receive data transmitted from an external device, receive power to transfer to elements and components within the mobile terminal 100, or transmit internal data of the mobile terminal 100 to such external device. The interface unit 160 may include wired or wireless headset ports, external power supply ports, wired or wireless data ports, memory card ports, ports for connecting a device having an identification module, audio input/output (I/O) ports, video I/O ports, earphone ports, or the like.

The identification module may be a chip that stores various information for authenticating authority of using the mobile terminal 100 and may include a user identity module (UIM), a subscriber identity module (SIM), a universal subscriber identity module (USIM), and the like. In addition, the device having the identification module (also referred to herein as an “identifying device”) may take the form of a smart card. Accordingly, the identifying device can be connected with the terminal 100 via the interface unit 160.

When the mobile terminal 100 is connected with an external cradle, the interface unit 160 can serve as a passage to allow power from the cradle to be supplied to the mobile terminal 100 or may serve as a passage to allow various command signals input by the user from the cradle to be transferred to the mobile terminal there through. Various command signals or power input from the cradle may operate as signals for recognizing that the mobile terminal is properly mounted on the cradle.

The memory 170 can store programs to support operations of the controller 180 and store input/output data (for example, phonebook, messages, still images, videos, etc.). The memory 170 may store data related to various patterns of vibrations and audio which are output in response to touch inputs on the touch screen.

The memory 170 may include one or more types of storage mediums including a Flash memory, a hard disk, a solid state disk, a silicon disk, a multimedia card micro type, a card-type memory (e.g., SD or DX memory, etc), a Random Access Memory (RAM), a Static Random Access Memory (SRAM), a Read-Only Memory (ROM), an Electrically Erasable Programmable Read-Only Memory (EEPROM), a Programmable Read-Only memory (PROM), a magnetic memory, a magnetic disk, an optical disk, and the like. The mobile terminal 100 may also be operated in relation to a network storage device that performs the storage function of the memory 170 over a network, such as the Internet.

The controller 180 may typically control the general operations of the mobile terminal 100. For example, the controller 180 may set or release a lock state for restricting a user from inputting a control command with respect to applications when a status of the mobile terminal meets a preset condition.

The controller 180 can also perform the controlling and processing associated with voice calls, data communications, video calls, and the like, or perform pattern recognition processing to recognize a handwriting input or a picture drawing input performed on the touch screen as characters or images, respectively. In addition, the controller 180 can control one or a combination of those components in order to implement various exemplary embodiments disclosed herein.

The power supply unit 190 receives external power or provides internal power and supply the appropriate power required for operating respective elements and components included in the mobile terminal 100. The power supply unit 190 may include a battery, which is typically rechargeable or be detachably coupled to the terminal body for charging.

The power supply unit 190 may include a connection port. The connection port may be configured as one example of the interface unit 160 to which an external charger for supplying power to recharge the battery is electrically connected.

As another example, the power supply unit 190 may be configured to recharge the battery in a wireless manner without use of the connection port. In this example, the power supply unit 190 can receive power, transferred from an external wireless power transmitter, using at least one of an inductive coupling method which is based on magnetic induction or a magnetic resonance coupling method which is based on electromagnetic resonance.

Various embodiments described herein may be implemented in a computer-readable medium, a machine-readable medium, or similar medium using, for example, software, hardware, or any combination thereof.

Referring now to FIGS. 1B and 1C, the mobile terminal 100 is described with reference to a bar-type terminal body. However, the mobile terminal 100 may alternatively be implemented in any of a variety of different configurations. Examples of such configurations include watch-type, clip-type, glasses-type, or as a folder-type, flip-type, slide-type, swing-type, and swivel-type in which two and more bodies are combined with each other in a relatively movable manner, and combinations thereof. Discussion herein will often relate to a particular type of mobile terminal (for example, bar-type, watch-type, glasses-type, and the like). However, such teachings with regard to a particular type of mobile terminal will generally apply to other types of mobile terminals as well.

The mobile terminal 100 will generally include a case (for example, frame, housing, cover, and the like) forming the appearance of the terminal.

In this embodiment, the case is formed using a front case 101 and a rear case 102. Various electronic components are incorporated into a space formed between the front case 101 and the rear case 102. At least one middle case may be additionally positioned between the front case 101 and the rear case 102.

The display unit 151 is shown located on the front side of the terminal body to output information. As illustrated, a window 151a of the display unit 151 may be mounted to the front case 101 to form the front surface of the terminal body together with the front case 101.

In some embodiments, electronic components may also be mounted to the rear case 102. Examples of such electronic components include a detachable battery 191, an identification module, a memory card, and the like. Rear cover 103 is shown covering the electronic components, and this cover may be detachably coupled to the rear case 102. Therefore, when the rear cover 103 is detached from the rear case 102, the electronic components mounted to the rear case 102 are externally exposed.

As illustrated, when the rear cover 103 is coupled to the rear case 102, a side surface of the rear case 102 is partially exposed. In some cases, upon the coupling, the rear case 102 may also be completely shielded by the rear cover 103. In some embodiments, the rear cover 103 may include an opening for externally exposing a camera 121b or an audio output module 152b.

The cases 101, 102, 103 may be formed by injection-molding synthetic resin or may be formed of a metal, for example, stainless steel (STS), aluminum (Al), titanium (Ti), or the like.

As an alternative to the example in which the plurality of cases form an inner space for accommodating components, the mobile terminal 100 may be configured such that one case forms the inner space. In this example, a mobile terminal 100 having a uni-body is formed in such a manner that synthetic resin or metal extends from a side surface to a rear surface.

If desired, the mobile terminal 100 may include a waterproofing unit (not shown) for preventing introduction of water into the terminal body. For example, the waterproofing unit may include a waterproofing member which is located between the window 151a and the front case 101, between the front case 101 and the rear case 102, or between the rear case 102 and the rear cover 103, to hermetically seal an inner space when those cases are coupled.

The mobile terminal 100 may be provided with the display unit 151, the 1st audio output unit 152a, the 2nd audio output unit 152b, the proximity sensor 141, the illumination sensor 142, the light output unit 154, the 1st camera 121a, the 2nd camera 121b, the 1st manipulating unit 123a, the 2nd manipulating unit 123b, the microphone 122, the interface unit 160, and the like.

FIGS. 1B and 1C depict certain components as arranged on the mobile terminal.

However, it is to be understood that alternative arrangements are possible and within the teachings of the instant disclosure. Some components may be omitted or rearranged. For example, the first manipulation unit 123a may be located on another surface of the terminal body, and the second audio output module 152b may be located on the side surface of the terminal body.

The display unit 151 outputs information processed in the mobile terminal 100. The display unit 151 may be implemented using one or more suitable display devices.

Examples of such suitable display devices include a liquid crystal display (LCD), a thin film transistor-liquid crystal display (TFT-LCD), an organic light emitting diode (OLED), a flexible display, a 3-dimensional (3D) display, an e-ink display, and combinations thereof.

The display unit 151 may be implemented using two display devices, which can implement the same or different display technology. For instance, a plurality of the display units 151 may be arranged on one side, either spaced apart from each other, or these devices may be integrated, or these devices may be arranged on different surfaces.

The display unit 151 may also include a touch sensor which senses a touch input received at the display unit. When a touch is input to the display unit 151, the touch sensor may be configured to sense this touch and the controller 180, for example, may generate a control command or other signal corresponding to the touch. The content which is input in the touching manner may be a text or numerical value, or a menu item which can be indicated or designated in various modes.

The touch sensor may be configured in a form of a film having a touch pattern, disposed between the window 151a and a display on a rear surface of the window 151a, or a metal wire which is patterned directly on the rear surface of the window 151a. Alternatively, the touch sensor may be integrally formed with the display. For example, the touch sensor may be disposed on a substrate of the display or within the display.

The display unit 151 may also form a touch screen together with the touch sensor. Here, the touch screen may serve as the user input unit 123 (see FIG. 1A). Therefore, the touch screen may replace at least some of the functions of the first manipulation unit 123a.

The first audio output module 152a may be implemented in the form of a speaker to output voice audio, alarm sounds, multimedia audio reproduction, and the like.

The window 151a of the display unit 151 will typically include an aperture to permit audio generated by the first audio output module 152a to pass. One alternative is to allow audio to be released along an assembly gap between the structural bodies (for example, a gap between the window 151a and the front case 101). In this case, a hole independently formed to output audio sounds may not be seen or is otherwise hidden in terms of appearance, thereby further simplifying the appearance and manufacturing of the mobile terminal 100.

The optical output module 154 can be configured to output light for indicating an event generation. Examples of such events include a message reception, a call signal reception, a missed call, an alarm, a schedule notice, an email reception, information reception through an application, and the like. When a user has checked a generated event, the controller can control the optical output unit 154 to stop the light output.

The first camera 121a can process image frames such as still or moving images obtained by the image sensor in a capture mode or a video call mode. The processed image frames can then be displayed on the display unit 151 or stored in the memory 170.

The first and second manipulation units 123a and 123b are examples of the user input unit 123, which may be manipulated by a user to provide input to the mobile terminal 100. The first and second manipulation units 123a and 123b may also be commonly referred to as a manipulating portion, and may employ any tactile method that allows the user to perform manipulation such as touch, push, scroll, or the like. The first and second manipulation units 123a and 123b may also employ any non-tactile method that allows the user to perform manipulation such as proximity touch, hovering, or the like.

FIG. 1B illustrates the first manipulation unit 123a as a touch key, but possible alternatives include a mechanical key, a push key, a touch key, and combinations thereof.

Input received at the first and second manipulation units 123a and 123b may be used in various ways. For example, the first manipulation unit 123a may be used by the user to provide an input to a menu, home key, cancel, search, or the like, and the second manipulation unit 123b may be used by the user to provide an input to control a volume level being output from the first or second audio output modules 152a or 152b, to switch to a touch recognition mode of the display unit 151, or the like.

As another example of the user input unit 123, a rear input unit (not shown) may be located on the rear surface of the terminal body. The rear input unit can be manipulated by a user to provide input to the mobile terminal 100. The input may be used in a variety of different ways. For example, the rear input unit may be used by the user to provide an input for power on/off, start, end, scroll, control volume level being output from the first or second audio output modules 152a or 152b, switch to a touch recognition mode of the display unit 151, and the like. The rear input unit may be configured to permit touch input, a push input, or combinations thereof.

The rear input unit may be located to overlap the display unit 151 of the front side in a thickness direction of the terminal body. As one example, the rear input unit may be located on an upper end portion of the rear side of the terminal body such that a user can easily manipulate it using a forefinger when the user grabs the terminal body with one hand. Alternatively, the rear input unit can be positioned at most any location of the rear side of the terminal body.

Embodiments that include the rear input unit may implement some or all of the functionality of the first manipulation unit 123a in the rear input unit. As such, in situations where the first manipulation unit 123a is omitted from the front side, the display unit 151 can have a larger screen.

As a further alternative, the mobile terminal 100 may include a finger scan sensor which scans a user's fingerprint. The controller 180 can then use fingerprint information sensed by the finger scan sensor as part of an authentication procedure. The finger scan sensor may also be installed in the display unit 151 or implemented in the user input unit 123.

The microphone 122 is shown located at an end of the mobile terminal 100, but other locations are possible. If desired, multiple microphones may be implemented, with such an arrangement permitting the receiving of stereo sounds.

The interface unit 160 may serve as a path allowing the mobile terminal 100 to interface with external devices. For example, the interface unit 160 may include one or more of a connection terminal for connecting to another device (for example, an earphone, an external speaker, or the like), a port for near field communication (for example, an Infrared Data Association (IrDA) port, a Bluetooth port, a wireless LAN port, and the like), or a power supply terminal for supplying power to the mobile terminal 100. The interface unit 160 may be implemented in the form of a socket for accommodating an external card, such as Subscriber Identification Module (SIM), User Identity Module (UIM), or a memory card for information storage.

The second camera 121b is shown located at the rear side of the terminal body and includes an image capturing direction that is substantially opposite to the image capturing direction of the first camera unit 121a. If desired, second camera 121a may alternatively be located at other locations, or made to be moveable, in order to have a different image capturing direction from that which is shown.

The second camera 121b can include a plurality of lenses arranged along at least one line. The plurality of lenses may also be arranged in a matrix configuration. The cameras may be referred to as an “array camera.” When the second camera 121b is implemented as an array camera, images may be captured in various manners using the plurality of lenses and images with better qualities.

As shown in FIG. 1C, a flash 124 is shown adjacent to the second camera 121b. When an image of a subject is captured with the camera 121b, the flash 124 may illuminate the subject.

As shown in FIG. 1B, the second audio output module 152b can be located on the terminal body. The second audio output module 152b may implement stereophonic sound functions in conjunction with the first audio output module 152a, and may be also used for implementing a speaker phone mode for call communication.

At least one antenna for wireless communication may be located on the terminal body. The antenna may be installed in the terminal body or formed by the case. For example, an antenna which configures a part of the broadcast receiving module 111 may be retractable into the terminal body. Alternatively, an antenna may be formed using a film attached to an inner surface of the rear cover 103, or a case that includes a conductive material.

A power supply unit 190 for supplying power to the mobile terminal 100 may include a battery 191, which is mounted in the terminal body or detachably coupled to an outside of the terminal body. The battery 191 may receive power via a power source cable connected to the interface unit 160.

Also, the battery 191 can be recharged in a wireless manner using a wireless charger. Wireless charging may be implemented by magnetic induction or electromagnetic resonance.

The rear cover 103 is shown coupled to the rear case 102 for shielding the battery 191, to prevent separation of the battery 191, and to protect the battery 191 from an external impact or from foreign material. When the battery 191 is detachable from the terminal body, the rear case 103 may be detachably coupled to the rear case 102.

An accessory for protecting an appearance or assisting or extending the functions of the mobile terminal 100 can also be provided on the mobile terminal 100. As one example of an accessory, a cover or pouch for covering or accommodating at least one surface of the mobile terminal 100 may be provided. The cover or pouch may cooperate with the display unit 151 to extend the function of the mobile terminal 100. Another example of the accessory is a touch pen for assisting or extending a touch input to a touch screen.

Further preferred embodiments will be described in more detail with reference to additional drawing figures. It is understood by those skilled in the art that the present features can be embodied in several forms without departing from the characteristics thereof.

A web search engine indicates a software system designed to search for information of WWW (World Wide Web). Before a market of a mobile terminal is expanded, users have used a service of the web search engine using a PC (personal computer).

Recently, as the use of a mobile terminal is rapidly increasing in a manner of disseminating a huge amount of smartphones, percentage of the use of a web search engine using the mobile terminal is also increasing.

In case of using the service via a mobile terminal, it is able to not only access a web page of the web search engine using a web browser application but also access the web search engine via an application provided by the web search engine itself.

Meanwhile, services or contents provided on a web page have changed as well. Images or texts used to be provided on a legacy web page as main contents. Yet, not only the images or the texts but also such metadata as location information, tag information and the like are provided on a recent web page.

Location information corresponds to a geographical location. Similar to what is used in a GPS, the location information consists of longitude and latitude. Not only the longitude and the latitude, location information (address and the like) of an administrative district may correspond to the location information as well.

For instance, in case of a web page displaying information on a specific restaurant, the web page can include a picture of the specific restaurant, a picture (image content) of food of the restaurant and explanation (text contents) on the pictures. Additionally, location of the restaurant can be included in the location information content.

As mentioned in the foregoing description, while the recent web page provides various contents, a search result provided by the web search engine does not include information on the contents, thereby causing inconvenience. Hence, one embodiment of the present invention described in the following proposes to provide the information on the various contents on a service provided by the web search engine. In the following, a specific embodiment is explained with reference to drawings.

Meanwhile, according to the present invention, information processed in a mobile terminal can be displayed using a flexible display. Regarding this, it is explained in more detail in the following with reference to the attached drawings.

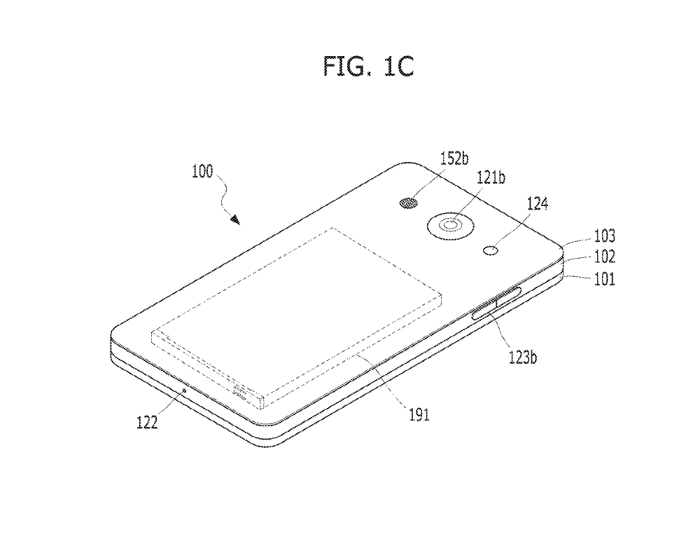

FIG. 2 is a diagram to describe a configuration of an input device according to an embodiment of the present invention.

An input device 130 includes a first coil 131, a second coil 132, a third coil 133, a fourth coil, a sensing unit 140, a haptic module 153 and a controller 180.

The input device 130 may receive a signal designating at least one content among contents displayed according to the present invention from a user. Further, the signal designating at least one content may be received through a touch input or through a hard key or soft key input.

The input device 130 may receive an input selecting at least one content from a user. Further, the input device 130 may receive an input of generating an icon related to the function performable by a mobile terminal 100.

The input device 130 may include a direction key, a key pad, a dome switch, a touch pad, a jog wheel, a jog switch, and the like.

According to an embodiment of the present invention, the input device 130 may be combined with the mobile terminal 100, by which the present invention is non-limited. The input device 130 may be combined with various devices.

The first coil 131 receives a touch input from a user and transmits the received touch input to at least one another coil.

When the first coil 131 is moved in a first direction according to the received touch input, the second coil 132 is electrically connected to the first coil 131 according to the movement of the first coil 131 and generates induced electromotive force.

According to an embodiment of the present invention, in a 3-dimensional coordinate system, a first direction refers to an X-axis movement direction of the first coil, a second direction refers to a y-axis movement direction of the first coil, and a third direction refers to a z-axis movement direction of the first coil 131.

When the first coil is moved in the second direction according to the received touch input, the third coil 133 is electrically connected to the first coil 131 according to the movement of the first coil 131 and generates induced electromotive force.

When the first coil 131 is moved in the third direction according to the received touch input, the fourth coil 134 is electrically connected to the first coil 131 according to the movement of the first coil 131 and generates induced electromotive force.

The sensing unit 140 senses the size of induced electromotive force and the pressure size of a touch input according to the movement of at least one of the first coil, the second coil 132, the third coil 133, and the fourth coil 134.

The haptic module 153 generates vibration. This was explained in detail with reference to FIG. 1A, and thus the description thereof is omitted here.

The controller 180 controls the first coil 131, the second coil 132, the third coil 133, the fourth coil 134, and the sensing unit 140.

The controller 180 time-divides a prescribed time and controls at least one of the second coil, the third coil and the fourth coil independently from a corresponding time in the time-divided prescribed time.

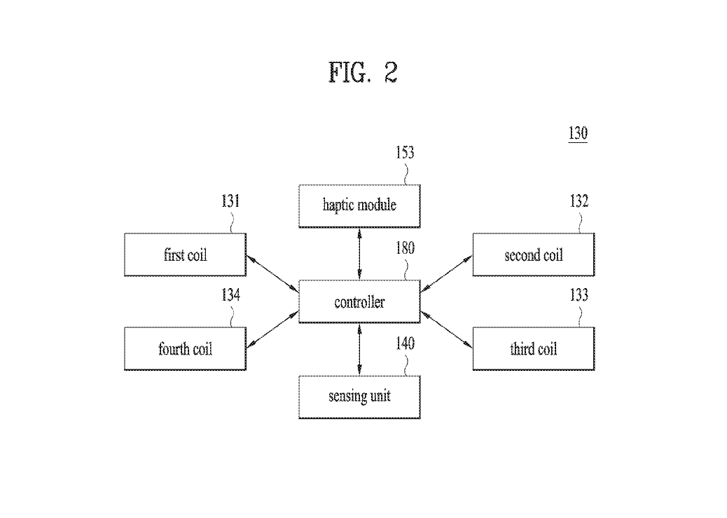

FIG. 3 is a flowchart of a controlling method of an input device according to an embodiment of the present invention. The present invention is performed by the controller 180.

Referring to FIG. 3, a touch input is received from a user (S310).

The received touch input is transmitted to at least another coil through the first coil 131 (S320).

When the first coil 131 is moved in the first direction according to the received touch input, the first coil 131 and the second coil 132 are electrically connected according to the movement of the first coil 131 (S330).

Induced electromotive force is generated based on the connected first and second coils 131 and 132 (S340).

When the first coil 131 is moved in the second direction according to the received touch input, the first coil 131 and the third coil 133 are electrically connected according to the movement of the first coil 131 (S350).

Induced electromotive force is generated based on the connected first and third coils 131 and 133 (S360).

When the first coil 131 is moved in the third direction according to the received touch input, the first coil 131 and the fourth coil 134 are electrically connected according to the movement of the first coil 131 (S370).

Induced electromotive force is generated based on the connected first and fourth coils 134 (S380).

The size of the induced electromotive force and the pressure size of a touch input are sensed according to the movement of at least one of the first coil 131, the second coil 132, the third coil 133 and the fourth coil 134 (S390).

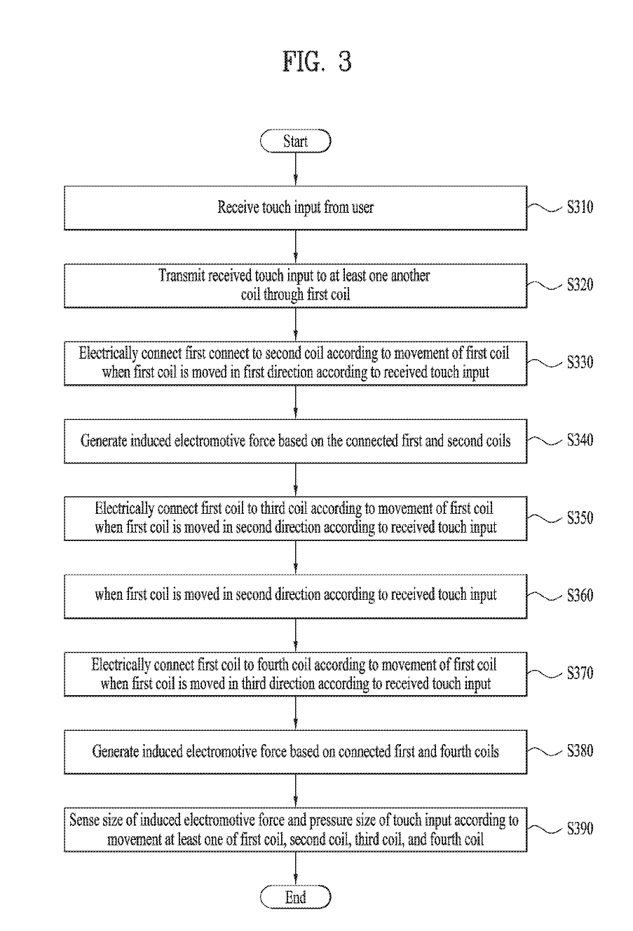

FIG. 4 is a perspective view diagram of an input device according to an embodiment of the present invention.

Referring to FIG. 4, if observed from the top, the first coil 131, the second coil 132, the third coil 133 and the fourth coil 134 are arranged in order.

Particularly, the second coil 132 corresponds to the x-axis displacement of the first coil 131, the third coil 133 corresponds to the y-axis displacement of the first coil 131, and the fourth coil 134 corresponds to the z-axis displacement of the first coil 131.

The size of the coil will be described as follows.

First of all, according to an embodiment of the present invention, there are a first coil 131, a second coil 132, a third coil 133 and a fourth coil 134. Among the four coils, the first coil 131 has the smallest size, and the fourth coil 134 has the largest size. Further, each of the second coil 132 and the third coil 133 has a size ranging between the size of the fourth coil 134 and the size of the first coil 131.

The fourth coil 134 has the largest size because the fourth coil 134 should include all of the first coil 131, the second coil 132 and the third coil 133.

The first coil 131 has the smallest size because the first coil 131 should generate induced electromotive force while moving between the second coil 132 and the third coil 133.

Referring to FIG. 4, when the first coil 131 is moved on the second coil 132, induced electromotive force is generated differently depending on the change of the size of the shared portion. Hence, the second coil 132 has a size greater than the size of the first coil 131. Likewise, the third coil 133 has a size greater than the size of the first coil 131.

The moving direction of the first coil 131 will be described as follows.

First of all, according to an embodiment of the present invention, in a 3-dimensional coordinate system, a first direction means an x-axis movement direction of the first coil 131, a second direction means a y-axis movement direction of the first coil 131, and a third direction means a z-axis movement direction of the first coil 131.

If a user pushes the first coil 131 with a finger 300, the first coil is moved in the third direction, i.e., a negative z-axis direction. In this case, the negative z-axis direction means a direction from the upper side of the ground to the lower side of the ground. A positive z-axis direction means a direction from the lower side of the ground to the upper side of the ground. If the user moves the first coil in the negative z-axis direction with the finger 300, the first coil 131 is electrically connected to the fourth coil 134 and generates induced electromotive force.

According to an embodiment of the present invention, the first coil 131 may be moved, and the second coil 132, the third coil 133 and the fourth coil 134 may be fixed.

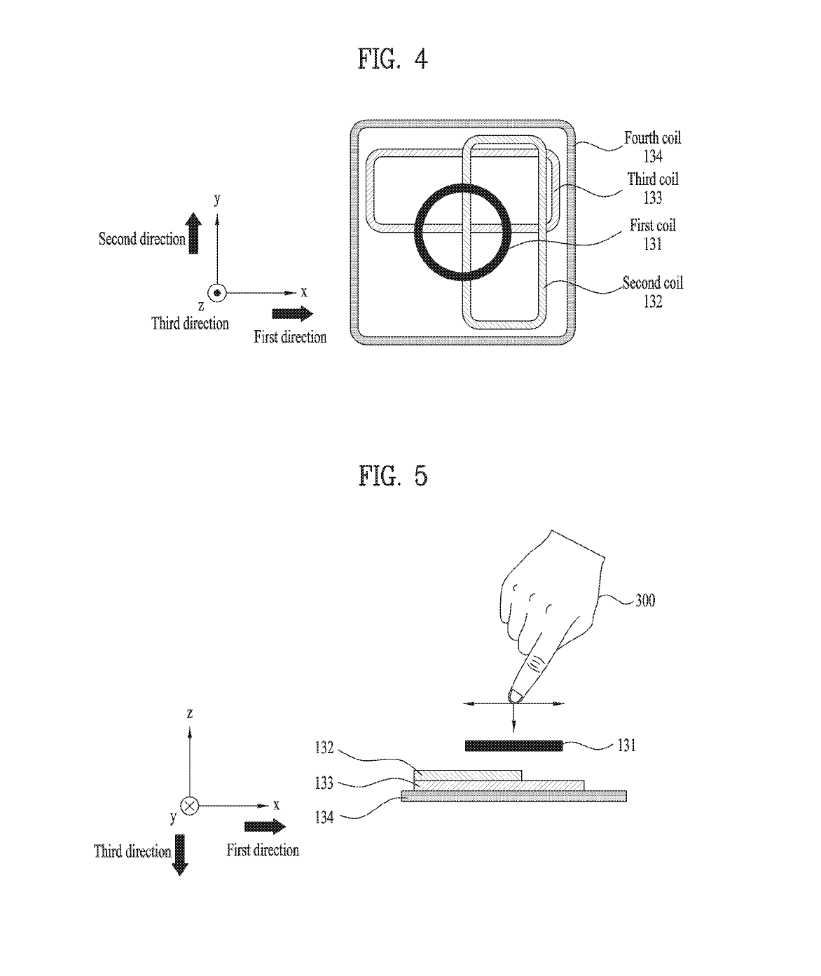

FIG. 5 is a lateral view diagram of an input device according to an embodiment of the present invention.

The fourth coil 134 is located on the bottom, and the third coil 133 is located on the fourth coil 134. The second coil 132 is located on the third coil 133. The second coil 132 and the first coil 131 are spaced apart from each other by a space of a prescribed distance.

If the user pushes the first coil 131 with the finger 300, the first coil is moved in the third direction, i.e., the negative z-axis direction. If the user moves the first coil in the negative z-axis direction with the finger 300, the first coil 131 is electrically connected to the fourth coil 134 and generates induced electromotive force.

If the user pushes the first coil 131 in a specific direction, the first coil is moved in the first direction, i.e., the x-axis direction. In this case, the x-axis direction means a direction from left to right.

For example, if the user moves the first coil 131 in the x-axis direction with the finger 300, the first coil 131 is electrically connected to the second coil 132 and generates induced electromotive force.

When the first coil 131 is moved in the y-axis direction, the above case is similarly applied. In this case, the y-axis direction means a direction from the upper side of the ground to the lower side of the ground.

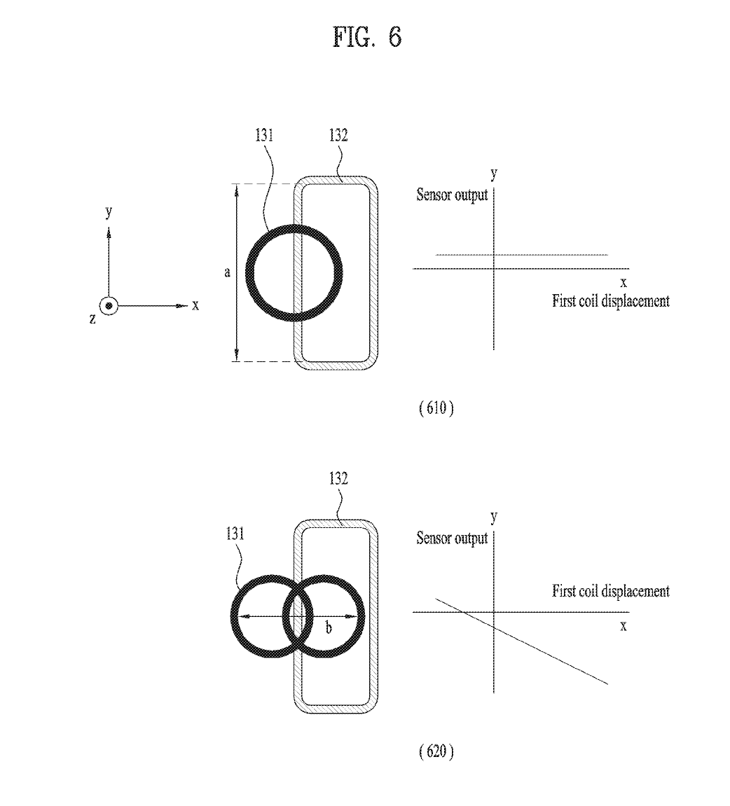

FIG. 6 is a diagram to describe a first coil displacement and a sensor output when a first coil is moved in the state that a second coil is fixed according to an embodiment of the present invention.

Referring to an embodiment 610 of FIG. 6, the first coil 131 is moved on the second coil 132 in the y-axis direction. In this case, “a” refers to a vertical length of the second coil 132. When the first coil 131 is moved on the second coil 132 in the y-axis direction, induced electromotive force is rarely generated between the first coil 131 and the second coil 132.

Therefore, if the first coil displacement is set as the x-axis and the sensor output of the sensing unit 140 is set as the y-axis, the sensor output change is maintained constant.

Referring to an embodiment 620, the first coil 131 is moved on the second coil 132 in the x-axis direction. In this case, “b” is a range where the first coil 131 may be moved on the second coil 132. When the first coil 131 is moved on the second coil 132 in x-axis direction, induced electromotive force is generated between the first coil 131 and the second coil 132.

Therefore, if the first coil displacement is set as x-axis and the sensor output of the sensing unit is set as y-axis, the sensor output has linearity.

Embodiments 610 and 620 are applied in the same manner in the relation with the first coil 131 and the third coil 133.

According to the present invention, when the first coil is moved in one of the first direction, the second direction and the third direction depending on the received touch input, the size of the sensor output sensed in the sensing unit 140 is linearly changed.

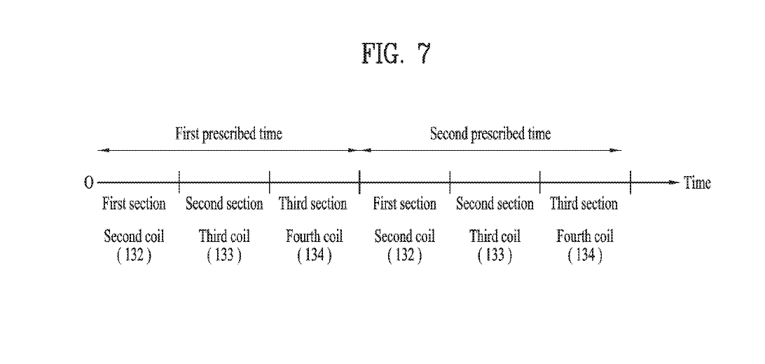

FIG. 7 is a diagram to describe time-division of a prescribed time and control of at least one of the second coil, the third coil and the fourth coil independent from a corresponding time in the time-divided prescribed time.

Referring to FIG. 7, a controller 180 time-divides a prescribed time and controls at least one of the second coil, the third coil and the fourth coil independently from a corresponding time in the time-divided prescribed time.

For example, the controller 180 may divide the first prescribed time into a first section, a second section and a third section at intervals of prescribed time. The controller 180 matches the first section with the second coil 132, matches the second section with the third coil 133 and matches the third section with the fourth coil 134.

The above case also applies to the case that the controller 180 divides the second prescribed section at intervals of prescribed time.

The second coil 132, the third coil 133 and the fourth coil 134 generate induced electromotive force, thereby having a possibility of respectively receiving signal interference.

According to the present invention, by time-dividing the first prescribed time at prescribed time intervals, the controller independently operates the second coil, the third coil and the fourth coil at each determined time, and thus it is possible to decrease the possibility of receiving signal interference among the second coil, the third coil and the fourth coil.

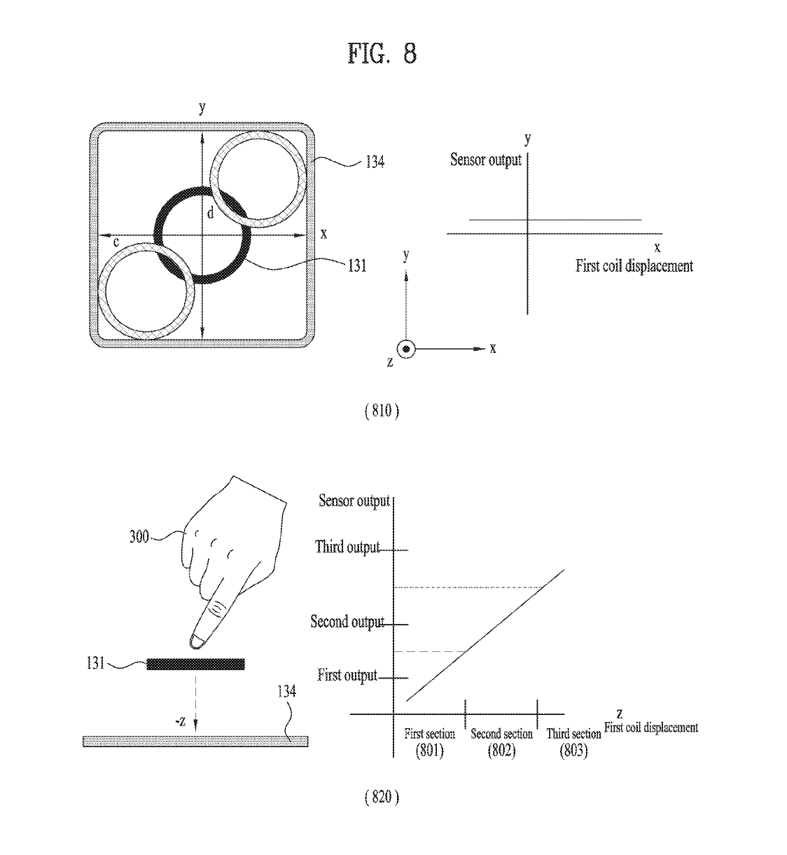

FIG. 8 is a diagram to describe a first coil displacement and a sensor output when a first coil is moved in the state that a fourth coil is fixed.

Referring to embodiment 810 of FIG. 8, the first coil 131 is moved in an x-axis or a y-axis direction within the range of the fourth coil 134. In this case, “c” means a horizontal length of the fourth coil 134 and “d” means a vertical length of the fourth coil 134.

When the first coil 131 is moved on the x-axis in the x-axis direction within the c range without moving to the z-axis on the fourth coil 134 and is moved on the y-axis in y-axis direction within the d range, induced electromotive force is rarely generated between the first coil 131 and the fourth coil 134.

Therefore, if the first coil displacement is set as x-axis and the sensor output of the sensing unit 140 is set as y-axis, the sensor output change is maintained constant.

Referring to an embodiment 820 of FIG. 8, if a user pushes the first coil 131 with a finger 300, the first coil 131 is moved on the fourth coil 134 in a negative z-axis direction. When the first coil 131 is moved on the fourth coil 134 in the negative z-axis direction, induced electromotive force is generated between the first coil 131 and the fourth coil 134.

Therefore, if the first displacement is set as the x-axis and the sensor output of the sensing unit 140 is set as the y-axis, the sensor output has linearity.

According to the present invention, when the first coil 131 is moved in the third direction, i.e., the negative z-axis direction, the size of the sensed sensor output is linearly changed.

Referring to the embodiment 820, the controller 180 regulates the output of the sensing unit 140 differently based on the pressure size of the touch input in a specific direction received from the first coil 131.

For example, the sizes of the touch pressure may be a first pressure, a second pressure, and a third pressure. The first pressure is smaller than the second pressure, and the second pressure is smaller than the third pressure.

When the pressures of the touch input are the first pressure, the second pressure, and the third pressure, the outputs of the sensing unit 140 become the first output, the second output, and third output.

The size of the first output is smaller than the size of the second output, and the size of the second output is smaller than the size of the third output.

The controller 180 divides a moving distance of the first coil 131 in a specific direction into a prescribed number of sections and regulates the output of the sensing unit 140 differently by sections based on the pressure size of the touch input.

Referring to the embodiment 820, the controller 180 divides the moving distance of the first coil 1310 in the z-axis direction into a prescribed number of sections. The prescribed number of sections may include a first section 801, a second section 802, and a third section 803.

The sizes of the touch input may be the first pressure, the second pressure, and the third pressure. Among them, the first pressure is the smallest and the third pressure is the largest.

The sizes of the sensor output may be the first output, the second output, and the third output. Among them, the first output has the smallest size, and the third output has the largest size.

If the pressure of the touch input is the first pressure, the first coil displacement becomes the first section. When the first coil displacement is the first section 801, the controller 180 adjusts the output of the sensing unit 140 as the first output.

If the pressure of the touch input is the second pressure, the first coil displacement becomes the second section 802. If the first coil displacement is the second section 802, the controller 180 adjusts the output of the sensing unit 140 as the second output.

If the pressure of the touch input is the third pressure, the first coil displacement becomes the third section 803. When the first coil displacement is the third section 803, the controller 180 adjusts the output of the sensing unit 140 as the third output.

The haptic module 153 generates vibration.

The controller 180 controls the haptic module 153 so that vibration may be generated differently depending on the pressure size of the touch input received by the first coil 131.

The sizes of the vibration output of the haptic module 153 may include the first output, the second output, and the third output. Among them, the first output has the smallest size, and the third output has the largest size.

If the pressure of the touch input is the first pressure, the first coil displacement becomes the first section 801. If the first coil displacement is the first section 801, the controller 180 adjusts the output of the haptic module 153 as the first output.

If the pressure of the touch input is the second pressure, the first coil displacement becomes the second section 802. When the first coil displacement is the second section 802, the controller 180 adjusts the output of the haptic module 153 as the second output.

If the pressure of the touch input is the third pressure, the first coil displacement becomes the third section 803. When the first coil displacement is the third section, the controller 180 adjusts the output of the haptic module 153 as the third output.

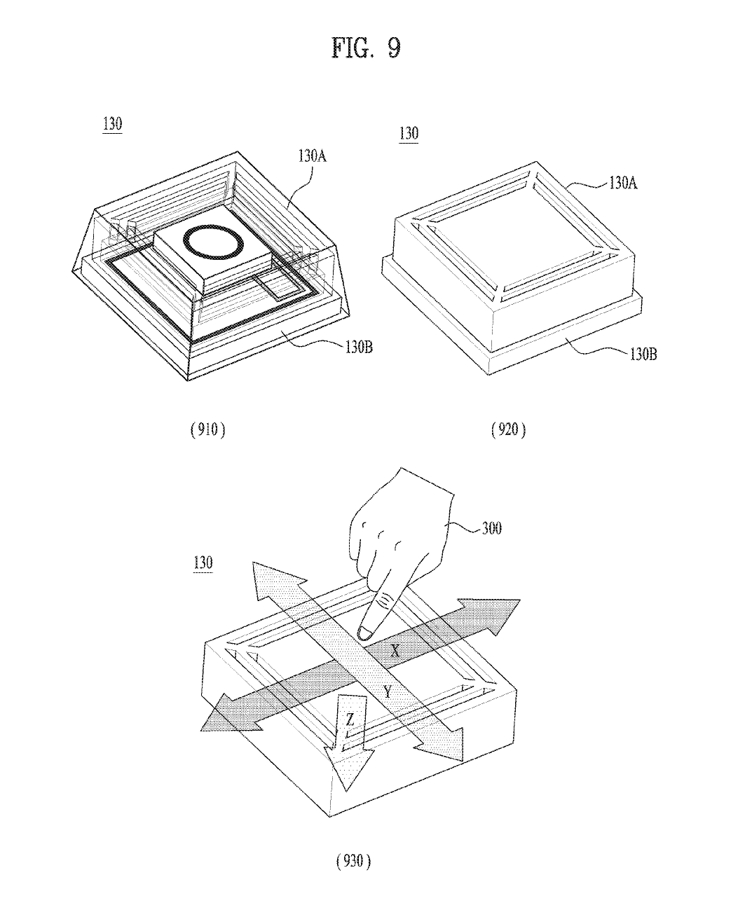

FIG. 9 is a diagram to describe an input device embodied as a product according to an embodiment of the present invention.

Referring to FIG. 9, the input device 130 includes an upper case 130A and a lower case 130B. According to an embodiment 910, the upper case 130A may be a silicon case.

Referring to an embodiment 920, the upper case 130A may be a PCB case, and the lower case 130B may be a PCB case. In this case, the PCB is an abbreviation of printed circuit board, which expresses electric wiring for connecting circuit parts as a wiring figure based on a circuit design and reproduces an electric conductor on an insulator through an appropriate scheme.

Referring to an embodiment 930, an input device 130 senses a movement using a triaxial sensor.

The input device 130 senses the movements on x-axis and y-axis as the change of the plane coordinates and senses the movement on z-axis as the change of z-axis coordinates when the user pushes a specific point with the finger 300.

According to an embodiment of the present invention, silicon rubber may be embodied into a spring shape, which may be applied to the upper case 130A and the lower case 130B. Further, a plate spring, a magnet, and the like may be used so as to be applied to the upper case 130A and the lower case 130B.

In this case, the input device 130 sets reaction force for each axis differently by time zones so that the mechanical reaction of x-axis, y-axis, and z-axis are not interfered each other.

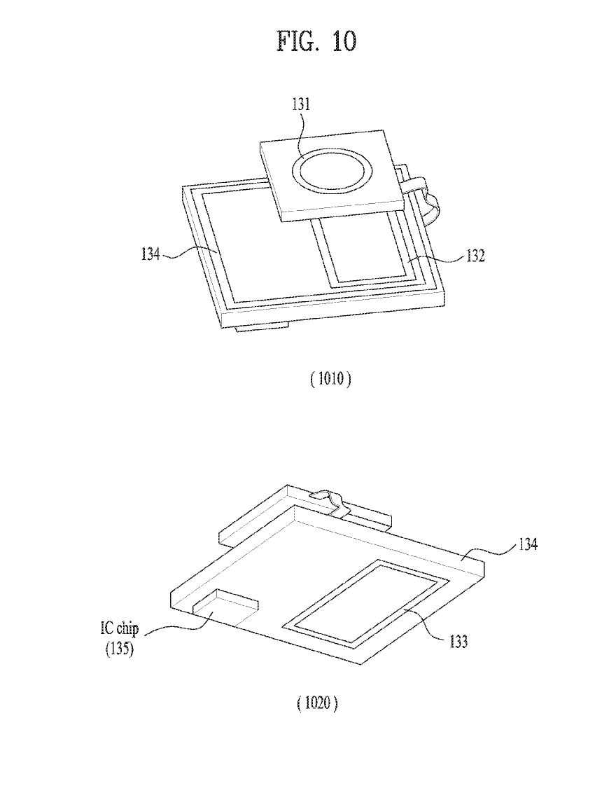

FIG. 10 is a diagram to describe an input device embodied as a PCB product according to an embodiment of the present invention.

Referring to an embodiment 1010 of FIG. 10, a second coil 132 is arranged on a fourth coil 134, and a first coil 131 is arranged on the second coil 132. The first coil is spaced apart from the second coil 132 by more than a prescribed distance.

In this case, the first coil 131 is a transmitting unit coil which is movable and transmits electromagnetic induction signal to another coil. The second coil 132 is a receiving unit coil related to the movement of x-axis of the first coil 131, and the fourth coil 134 is a receiving unit coil related to the movement of z-axis of the first coil 131.

Referring to an embodiment 1020, a third coil 133 is arranged under a fourth coil 134. Further, the third coil 133 may be arranged on the fourth coil 134. An IC chip 135 is arranged under the fourth coil 134. In this case, the IC chip 135 is a driver IC. The driver IC means a software component allowing mutual communication between an operating system and a device.

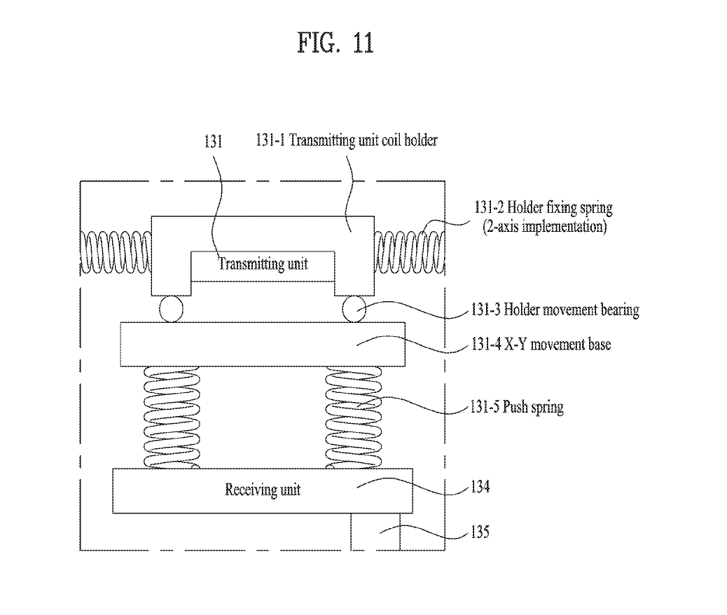

FIG. 11 is a diagram to describe an input device embodied into an instrument according to one embodiment of the present invention.

Referring to FIG. 11, an input device 130 includes a first coil 131, a transmitting unit coil holder 131-1, a holder fixing spring 131-2 embodied with 2 axes, a holder movement bearing 131-3, an x-y movement base 131-4, a push spring 131-5, a fourth coil 134, and an IC chip 135.

The first coil 131 performs the function of the transmitting unit, and the fourth coil 134 performs the function of the receiving unit.

The embodiment of FIG. 11 is merely an embodiment of the present invention, and the configuration and function of each component may be differently set.

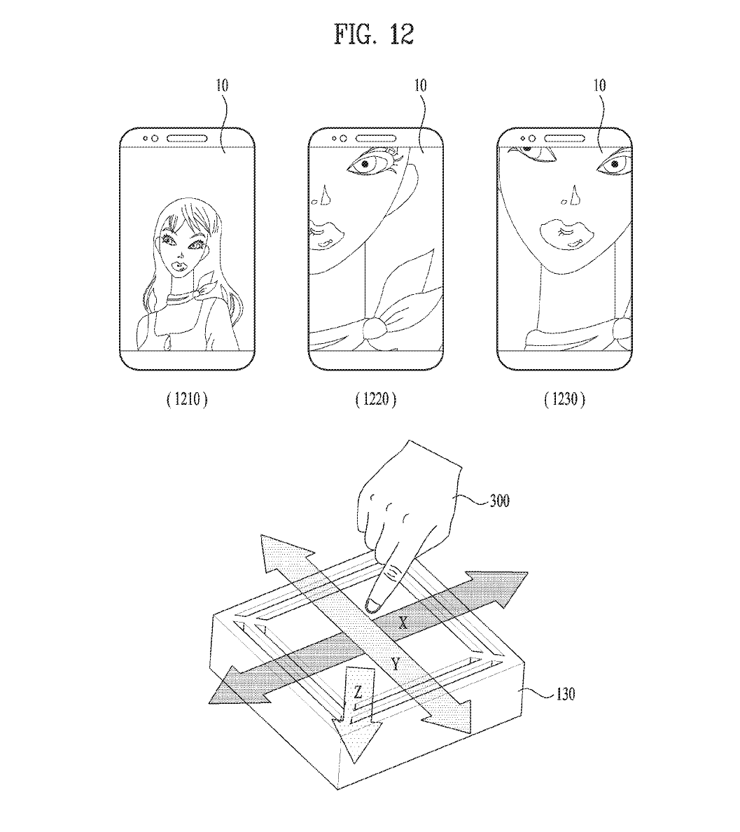

FIG. 12 is a diagram to describe adjustment of the size of a specific image and moving a specific image using an input device according to an embodiment of the present invention.

Referring to FIG. 12, if the first coil 131 is moved in a third direction in the state that a gallery application including a specific image 10 is running, the controller 180 executes a function of adjusting the size of the specific image 10. If the first coil 131 is moved in a specific direction corresponding to the first direction or the second direction, the controller 131 moves the specific image 10 in the specific direction.

In this case, the first direction, the second direction and the third direction may include the x-axis direction, the y-axis direction and the z-axis direction, respectively.

For example, if the first coil 131 is moved in the z-axis direction in the state that a gallery application including a specific image 10 is running, the controller 180 extends the size of the specific image 10 as illustrated in the embodiment 1220.

Further, when the first coil 131 is moved in the z-axis direction, the controller 180 may adjust the magnification ratio of the specific image 10 according to the pressure size of the touch input applied within a prescribed time.

Particularly, if the pressure size of the touch input is equal to or smaller than a first reference value, the first pressure is set. If the pressure size of the touch input is equal to or greater than the first reference value and is equal to or smaller than a second reference value, the second pressure is set. The first reference value is smaller than the second reference value.

When the first coil 131 is moved in the z-axis direction, if the pressure size of the touch input is equal to or smaller than the first reference value, the controller 180 sets the size of the touch input to the first pressure and enlarges the size of the specific image 10 by the first magnification ratio. If the first magnification ratio is smaller than 1, the size of the specific image is reduced.

When the first coil 131 is moved in the z-axis direction, if the pressure size of the touch input applied within a prescribed time is equal to or greater than the first reference value and is equal to or smaller than the second reference value, the controller 180 sets the size of the touch input to the second pressure and enlarges the specific image 10 by the second magnification ratio. If the first magnification ratio is greater than 1, the specific image 10 is enlarged. If the first magnification ratio is 1, the size of the specific image 10 is not changed.

If the first coil 131 is moved in a specific direction corresponding to the first direction or the second direction, the controller 180 moves the specific image 10 in the specific direction.

Referring to an embodiment 1230, if the first coil 131 is moved in the y-axis direction, the controller 180 moves the specific image 10 in the y-axis direction. If the first coil 11 is moved in the x-axis direction, the controller 180 moves the specific image 10 in the x-axis direction.

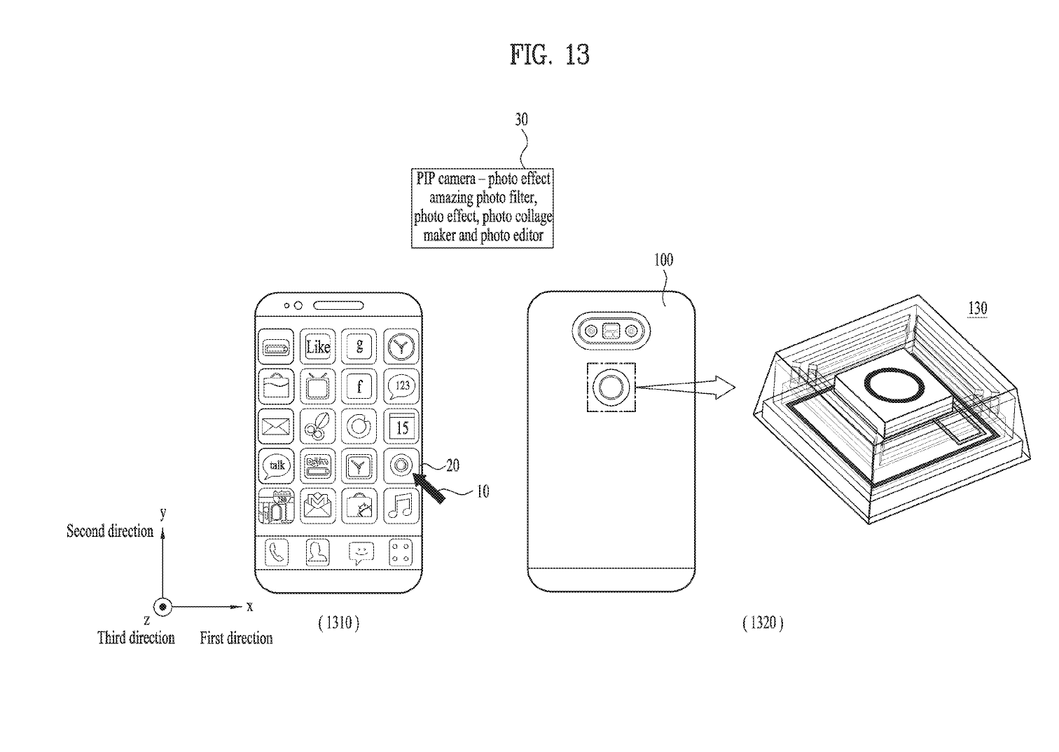

FIG. 13 is a diagram to describe execution of a function corresponding to a specific icon indicated by a specific pointer using an input device according to an embodiment of the present invention.

Referring to an embodiment 1310 of FIG. 13, in the state that a specific pointer 10 and a specific icon 20 are displayed, if the first coil 131 is moved in a specific direction corresponding to the first direction or the second direction, the controller 180 moves the specific pointer 10 in the specific direction, and if the first coil 131 is moved in the third direction, the controller 180 executes the function corresponding to the specific icon indicated by the specific pointer 10.

For example, if the first coil 131 is moved in the x-axis direction, the controller 180 moves the specific pointer 10 in the x-axis direction.

If the first coil 131 is moved in a negative z-axis direction, the controller 180 executes a function corresponding to the specific icon 20 indicated by the specific pointer 10. For example, when the specific icon 20 is a camera icon, the controller 180 executes a camera application.

According to an embodiment of the present invention, an icon function may be executed differently depending on the pressure size of the touch input.

When the first coil 131 is moved in the negative z-axis direction, the controller 180 executes the function corresponding to the specific icon 20 differently based on the pressure size of the touch input.

For example, the pressure sizes of the touch input inputted within a prescribed time may be a first pressure and a second pressure. The first pressure is smaller than the second pressure. The first pressure is smaller than the reference pressure, and the second pressure is greater than the reference pressure. The specific icon 20 may be a camera icon.

When the pressure of the touch input is the first pressure, i.e., a user pushes the first coil 131 with a force that is weaker than that of the reference pressure, the controller 180 executes the camera application.

When the pressure of the touch input is the second pressure, i.e., the user pushes the first coil 131 with a force that is stronger than that of the reference pressure, the controller 180 displays a text box 30 explaining the function of the specific icon 20 on the screen. Therefore, the user may see the text box 30 explaining the function of the specific icon 20 and may intuitively recognize the function of the specific icon 20. The text box 30 includes the content about a PIP camera, an amazing photo filter, a photo effect, a photo collage maker, and a photo editor.

According to the present invention, the function corresponding to the specific icon 20 indicated by the specific pointer 10 may be executed differently depending on the pressure size of the touch input, thereby improving user convenience.

Referring to an embodiment 1320 of FIG. 13, the input device 130 may be placed on the backside of the mobile device 100.

According to the present invention, as the input device 130 is placed on the backside of the mobile device 100, the user may easily move the specific pointer and easily execute an application, thereby improving user convenience.

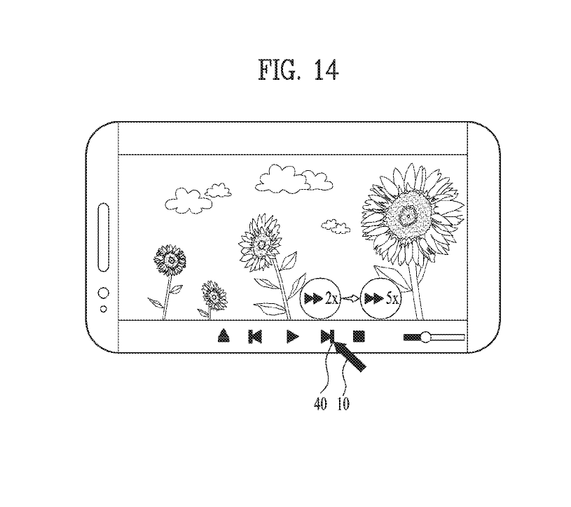

FIG. 14 is a diagram to describe adjustment of a moving picture play speed using an input device in a state that a moving picture application is running according to an embodiment of the present invention.

In a state that a moving picture application capable of adjusting a play speed is running, when the specific pointer 10 is positioned at a specific location 40, if the first coil 131 is moved in a specific direction, the controller 180 adjusts the moving picture play speed differently depending on the pressure size of the touch input.

In this case, the pressure sizes of the touch input applied within a prescribed time may be a first pressure and a second pressure. The size of the first pressure is smaller than that of the second pressure. The size of the first pressure is smaller than that of the reference pressure, and the size of the second pressure is greater than that of the reference pressure. A button for adjusting the play speed of a moving picture may be positioned at a specific location 40.

For example, when the specific pointer 10 is positioned at the specific location 40, if the first coil 131 is moved in the z-axis direction in the state that the pressure of the touch input is the first pressure, the controller 180 adjusts the play speed of a moving picture as the double speed.

Namely, when the user pushes the first coil with a pressure that is weaker than the reference pressure, the controller 180 adjusts the replay speed of the moving picture as the double speed.

For example, when the specific pointer 10 is positioned at the specific location 40, if the first coil 131 is moved in the z-axis direction in the state that the pressure of the touch input is the second pressure, the controller 180 adjusts the play speed of the moving picture as the 5-fold speed.

Namely, when the user pushes the first coil 131 with a pressure stronger than the reference pressure, the controller 180 adjusts the play speed of the moving picture as the 5-fold speed.

According to the present invention, the play speed of the moving picture may be adjusted differently depending on the pressure size of the touch input, thereby improving user convenience.

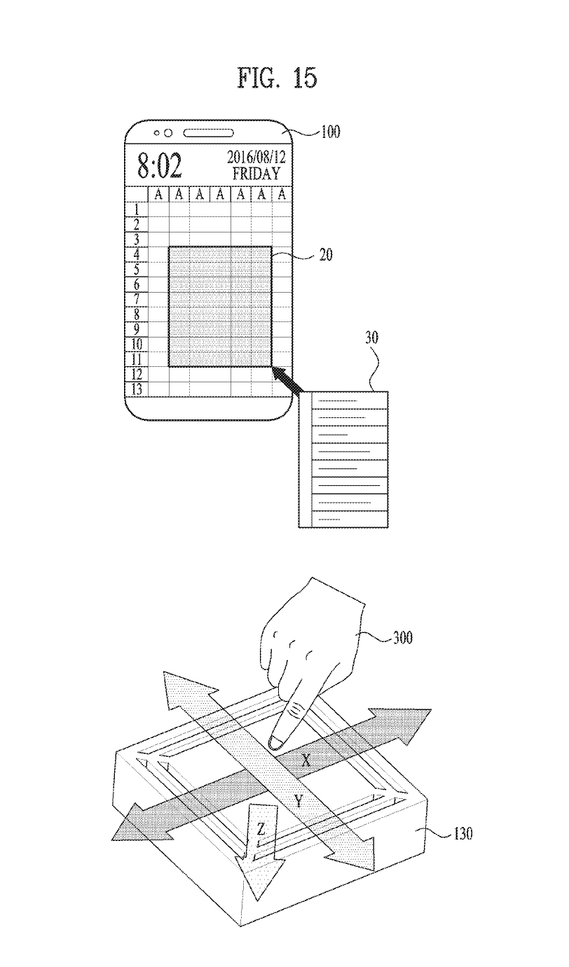

FIG. 15 is a diagram to describe editing of a document using an input device according to an embodiment of the present invention.

Referring to FIG. 15, in the state that a document editing application is running, if the user pushes the input device 130 in a z-axis direction with a finger 300, the controller 180 displays an indicator 20 capable of selecting a specific area. In the state that the indicator 20 is displayed, if a pointer 10 is moved in an x-axis direction or a y-axis direction, the controller 180 may adjust the size of the indicator 20 according to the movement of the pointer 10.

In this case, the input device 130 includes the first coil 131, and the movement of the input device 130 corresponds to the movement of the first coil 131.

If the input device 130 is pushed in the z-axis direction for a time that is equal to or greater than a prescribed time at a specific location, the controller 180 fixes the size of the indicator 20 and displays a document editing window 30.

According to the present invention, in the case that a document editing application is running in a mobile device 100, even when the user cannot touch a touch screen, a document can be edited, thereby improving user convenience.

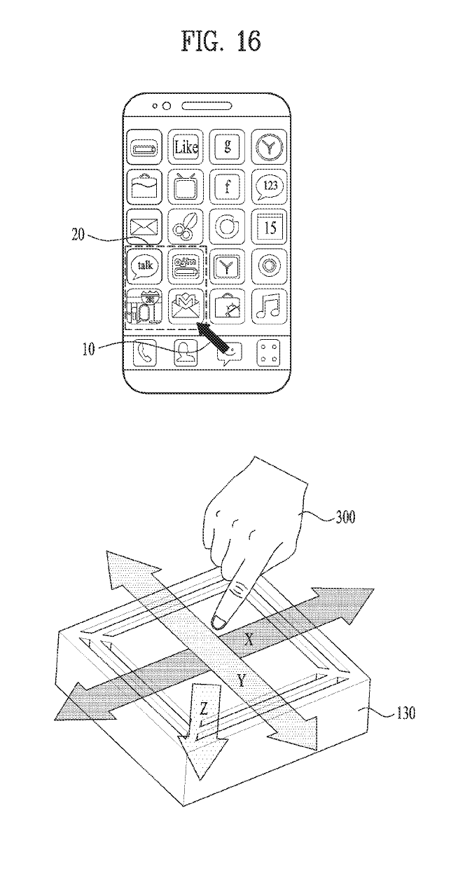

FIG. 16 is a diagram to describe grouping of a plurality of icons using an input device according to an embodiment of the present invention.

Referring to FIG. 16, in a home screen, if the user pushes an input device 130 in a z-axis direction with a finger 300, the controller 180 displays an indicator 20 capable of selecting a specific area. If the pointer 10 is moved in an x-axis direction or a y-axis direction in the state that the indicator 20 is displayed, the controller 180 may adjust the size of the indicator 20 according to the movement of the pointer 10.

If the input device 130 is pushed in the z-axis direction for more than a prescribed time at a specific location, the controller 180 fixes the size of the indicator 20 and groups at least one icon included in the indicator 20 as one group.

In this case, the at least one icon corresponds to a plurality of images in the state that a gallery application is running. Therefore, according to another embodiment of the present invention, a plurality of images may be grouped as one group.

According to the present invention, in a mobile device 100, in the state that a gallery application including a home screen and a plurality of images is running, even when a touch screen cannot be touched, icons can be grouped as one group, and thus the user convenience is improved.

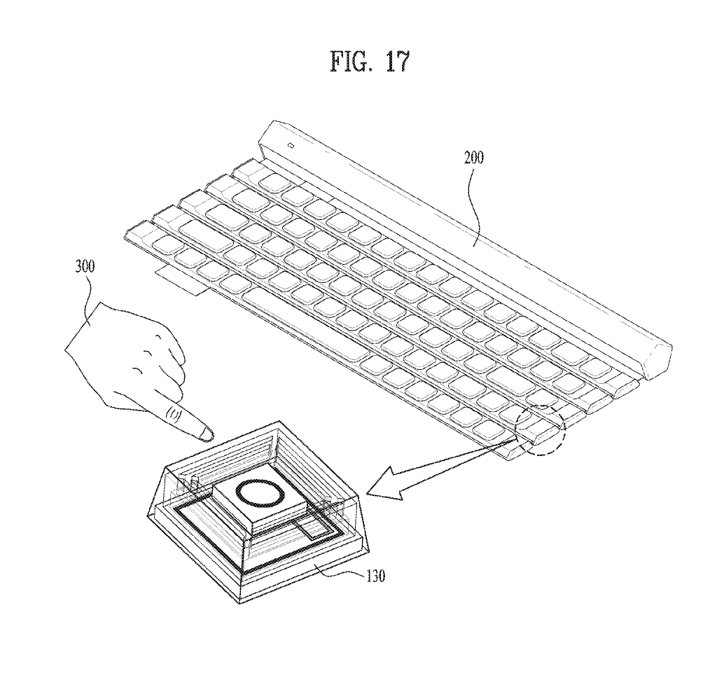

FIG. 17 is a diagram to describe application of an input device to a keyboard according to an embodiment of the present invention.

Referring to FIG. 17, if the user pushes an input device 130 in a z-axis direction with a finger 300 on a keyboard, the controller 180 executes a specific function. If a user moves the input device 130 in an x-axis or a y-axis direction, the controller 180 moves a mouse cursor (not shown) displayed on the screen in a corresponding direction.

Accordingly, embodiments of the present invention provide various effects and/or features.

According to at least one of embodiments of the present invention, various functions may be executed with a touch input to one input key using induced electromotive force, and thus it is not necessary to use a plurality of keys to execute various functions, thereby improving user convenience.

According to at least one of embodiments of the present invention, the output of the sensing unit may be adjusted differently based on the pressure size of the touch input in a specific direction received from a specific coil, and thus various functions can be executed with a touch input to one key, thereby improving user convenience.

According to at least one of embodiments of the present invention, a plurality of coils can be controlled independently at a time in a time-divided prescribed time in a manner of time-diving the prescribed time, and thus it is possible to prevent an interference phenomenon among a plurality of coils, thereby improving user convenience.

According to at least one of embodiments of the present invention, in a state that a gallery application including a specific image is running, if a specific coil is moved in a specific direction, the size of the specific image may be adjusted, and thus the magnification ratio of the specific image may be adjusted in a simple manner, thereby improving user convenience.

The above-described device control system can be implemented in a recording medium readable by a processor included in a device as processor-readable codes. The processor-readable recording media may include all kinds of recording devices in which data readable by a processor are stored. The processor-readable media may include ROM, RAM, CD-ROM, magnetic tapes, floppy discs, optical data storage devices, and the like for example and also include carrier-wave type implementations (e.g., transmission via Internet). Further, the processor-readable recording medium may be distributed in a computer system connected by a network, and thus processor-readable codes may be stored and executed in a distributed manner.

It will be appreciated by those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. An input device comprising:
a first coil configured to receive a touch input from a user and transmit the received touch input to at least one another coil;
a second coil configured to be electrically connected to the first coil according to a movement of the first coil and generate induced electromotive force when the first coil is moved in a first direction according to the received touch input;
a third coil configured to be electrically connected to the first coil according to the movement of the first coil and generate induced electromotive force when the first coil is moved in a second direction according to the received touch input;
a fourth coil configured to be electrically connected to the first coil according to the movement of the first coil and generate induced electromotive force when the first coil is moved in a third direction according to the received touch input; and
a sensing unit configured to sense a size of the induced electromotive force generated according to the movement of at least one of the first coil, the second coil, the third coil and the fourth coil, and a pressure size of the touch input.

2. The input device of claim 1, wherein the second coil corresponds to an x-axis displacement of the first coil,
wherein the third coil corresponds to a y-axis displacement of the first coil, and
the fourth coil corresponds to a z-axis displacement of the first coil.

3. The input device of claim 1, wherein among the first coil, the second coil, the third coil and the fourth coil, the fourth coil has a largest size, the first coil has a smallest size, and each of the second coil and the third coil has a size ranging between the size of the fourth coil and the size of the first coil.

4. The input device of claim 1, when the first coil is moved in one of the first direction, the second direction and the third direction according to the received touch input, the size of the induced electromotive force sensed by the sensing unit is linearly changed.

5. The input device of claim 1, further comprising a controller configured to control the first coil, the second coil, the third coil, the fourth coil and the sensing unit, wherein the controller is further configured to:
time divide a prescribed time, and
control at least one of the second coil, the third coil and the fourth coil independently from a corresponding time in the time-divided prescribed time.

6. The input device of claim 1, further comprising a haptic module configured to generate vibration,
wherein the controller is further configured to control the haptic module to generate vibration differently depending on a pressure size of the touch input received by the first coil.

7. The input device of claim 5, wherein the controller is further configured to adjust an output of the sensing unit differently based on a pressure size of the touch input in a specific direction received by the first coil.

8. The input device of claim 5, wherein the controller is further configured to:
divide a moving distance of the first coil in a specific direction into a prescribed number of sections, and
adjust an output of the sensing unit differently by the sections based on the pressure size of the touch input.

9. The input device of claim 5, wherein when a gallery application including a specific image is running,
the controller is further configured to:
execute a function of adjusting a size of the specific image if the first coil is moved in the third direction, and
move the specific image in the specific direction if the first coil is moved in a specific direction corresponding either to the first direction or to the second direction.

10. The input device of claim 9, wherein the controller is further configured to adjust a magnification ratio of the specific image according to the pressure size of the touch input when the first coil is moved in the third direction.

11. The input device of claim 9, wherein the controller is further configured to adjust a moving speed of the specific image differently depending on the pressure size of the touch input when the first coil is moved in a specific direction corresponding either to the first direction or to the second direction.

12. The input device of claim 5, wherein the controller is further configured to:
move the specific pointer in the specific direction when a specific pointer and a specific icon are displayed if the first coil is moved in a specific direction corresponding either to the first direction or to the second direction, and
execute a function corresponding to the specific icon indicated by the specific pointer if the first coil is moved in the third direction.

13. The input device of claim 12, wherein the controller is further configured to execute the function corresponding to the specific icon indicated by the specific pointer based on the pressure size of the touch input when the first coil is moved in the third direction.

14. The input device of claim 5, wherein the controller is further configured to adjust the play speed of a moving picture differently depending on the pressure size of the touch input when a moving picture application capable of adjusting a play speed is running, when a specific pointer is positioned at a specific location, if the first coil is moved in the specific direction.

15. A method of controlling an input device, comprising:
receiving a touch input from a user;
transmitting the received touch input to at least one another coil through the first coil;
electrically connecting the first coil to a second coil according to a movement of the first coil when the first coil is moved in a first direction according to the received touch input;
generating an induced electromotive force based on the connected first and second coils;
electrically connecting the first coil to a third coil according to the movement of the first coil when the first coil is moved in a second direction according to the received touch input;
generating the induced electromotive force based on the connected first and third coils;
electrically connecting the first coil to a fourth coil according to the movement of the first coil when the first coil is moved in a third direction according to the received touch input;
generating the induced electromotive force based on the connected first and fourth coils; and
sensing a size of the induced electromotive force generated according to the movement of at least one of the first coil, the second coil, the third coil and the fourth coil and a pressure size of the touch input.

16. The method of claim 15, wherein when the first coil is moved in one of the first direction, the second direction and the third direction, the size of the induced electromotive force sensed by a sensing unit is linearly changed.

17. The method of claim 15, further comprising:
time-dividing a prescribed time; and
controlling at least one of the second coil, the third coil and the fourth coil independently from a corresponding time in the time-divided prescribed time.

18. The method of claim 15, further comprising adjusting an output of the sensing unit differently based on a pressure size of the touch input in a specific direction received by the first coil.

19. The method of claim 15, further comprising:
dividing a moving distance of the first coil in a specific direction into a prescribed number of sections; and
adjusting an output of the sensing unit differently by the sections based on a pressure size of the touch input.

20. The method of claim 15, further comprising:
executing a function of enlarging a specific image if the first coil is moved in the third direction when a gallery application including the specific image is running; and
if the first coil is moved in a specific direction corresponding either to the first direction or to the second direction, moving the specific image in the specific direction.
